(19) United States
(12) Patent Application Publication
(10) Pub. No.: US 2023/0290421 A1
(43) Pub. Date: Sep. 14, 2023

(54) READOUT METHOD OF MEMORY MODULE INCLUDING ANTI-FUSE ELEMENT AND PRINTING APPARATUS

(71) Applicant: Canon Kabushiki Kaisha, Tokyo (JP)

(72) Inventors: RYOHEI YAMADA, Kanagawa (JP); TOSHIO NEGISHI, Kanagawa (JP)

(21) Appl. No.: 18/169,284

(22) Filed: Feb. 15, 2023

(30) Foreign Application Priority Data
Mar. 14, 2022 (JP) 2022-039554

(51) Int. Cl. G11C 17/18; G11C 17/16

(52) U.S. Cl. CPC G11C 17/18; G11C 17/16

(57) ABSTRACT

A readout method of a memory module of a substrate including the memory module including an anti-fuse element, and a function module connected in parallel with the memory module and including a resistance element, including setting the function module to a conducted state when reading out the memory module, setting the function module from the conducted state to an open state following the setting the function module to the conducted state, and reading out a terminal voltage of the anti-fuse element by setting the memory module to the conducted state following the setting the function module from the conducted state to the open state.

### BACKGROUND OF THE INVENTION

### Field of the Invention

The present invention relates to a readout method of a memory module including an anti-fuse element, and a printing apparatus.

### Description of the Related Art

In general, a print element substrate mounted on a liquid discharge head includes a One Time Programmable (OTP) ROM to record unique information such as product information and setting information. As an example of the OTPROM, there is an OTPROM using an anti-fuse element. In this ROM, since 1-bit information can be recorded in one anti-fuse element, a number of anti-fuse elements are mounted on the print element substrate. To read out information recorded in these anti-fuse elements, a driving element connected in series with each anti-fuse element is turned on, thereby measuring the terminal voltage of the anti-fuse element. Hence, to read out information of a number of anti-fuse elements, it is necessary to repeat an operation of sequentially turning on/off one driving element and measuring the terminal voltage of each anti-fuse element. Since a long time is taken to read out information of a number of anti-fuse elements, the readout operation needs to be speeded up.

Japanese Patent Laid-Open No. 10-106280 describes a potential control method when reading out the potential of a multivalue word line of a multivalue mask ROM. In the method described in Japanese Patent Laid-Open No. 10-106280, immediately before setting to a read potential, the potential of a word line is set to a potential higher than the read potential using a voltage source other than the read potential. The potential of the word line is made to quickly reach the read potential by temporarily over-precharging it to a high potential, thereby implementing shortening of the readout time.

However, if the ROM read method described in Japanese Patent Laid-Open No. 10-106280 is applied to the readout operation of the anti-fuse element mounted on the print element substrate, a power supply used to temporarily over-precharge the terminal voltage of the anti-fuse element and a driving circuit configured to control the potential of a readout line of the anti-fuse element are needed. Providing the power supply and the driving circuit on the print element substrate undesirably leads to an increase of cost.

The present invention solves at least one of the problems of the conventional technique.

### SUMMARY OF THE INVENTION

The present invention provides a technique of speeding up the readout operation of the terminal voltage of an anti-fuse element while suppressing an increase of cost.

According to one aspect of the present invention, there is provided a readout method of a memory module of a substrate including the memory module including an anti-fuse element, and a function module connected in parallel with the memory module and including a resistance element, comprising setting the function module to a conducted state when reading out the memory module, setting the function module from the conducted state to an open state following the setting the function module to the conducted state, and reading out a terminal voltage of the anti-fuse element by setting the memory module to the conducted state following the setting the function module from the conducted state to the open state.

Further aspects of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a circuit diagram showing the circuit configuration of a print element substrate according to the first embodiment.

FIG. 2 is a circuit diagram showing the circuit configuration of the print element substrate according to the first embodiment.

FIG. 3 is a view for explaining information write to an anti-fuse element of the memory module of the print element substrate according to the first embodiment.

FIG. 4 is a flowchart for explaining readout processing of the anti-fuse element by the control unit of an inkjet printing apparatus according to the first embodiment.

FIGS. 5A and 5B are views for explaining voltage waveforms in a readout operation of the anti-fuse element.

FIG. 6 is a circuit diagram showing the circuit configuration of a print element substrate according to the second embodiment.

FIG. 7 is a view for explaining the module groups of the print element substrate according to the second embodiment.

FIG. 8 is a perspective view showing a liquid discharge head according to the first embodiment.

FIG. 9 is a view for explaining the module groups of a print element substrate according to the third embodiment.

FIG. 10 is a connection diagram of an inkjet printing apparatus and the print element substrate according to the second embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

A print element substrate that discharges a liquid such as ink, a liquid discharge head, and a printing apparatus according to the present invention will now be described with reference to the accompanying drawings. Note that as an example of the present invention, a thermal type print element substrate will be described. However, the present invention is not limited to this, and can also be applied to a piezoelectric type print element substrate.

### First Embodiment

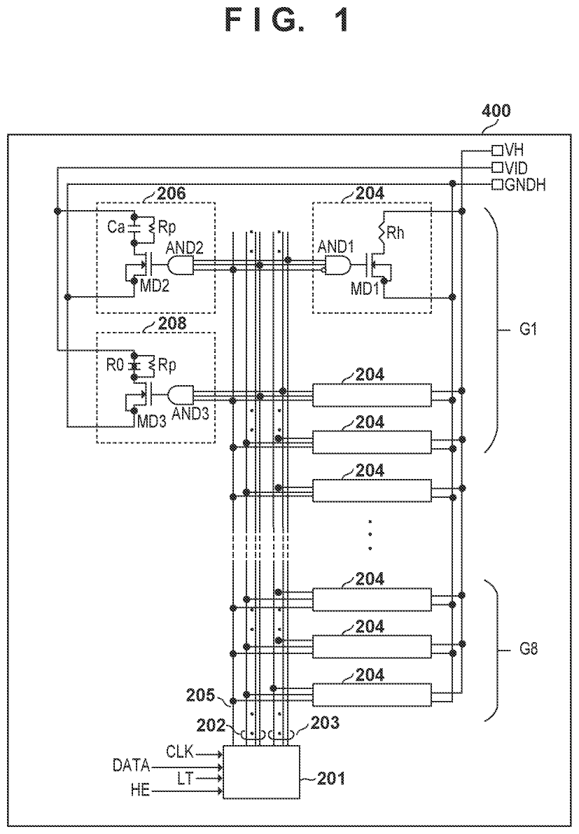

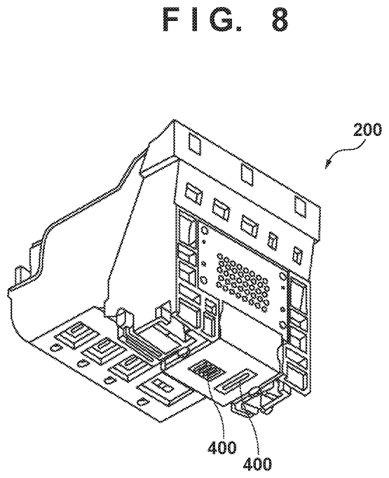

The first embodiment of the present invention will be described first with reference to FIGS. 1 and 8.

FIG. 8 is a perspective view showing a liquid discharge head (printhead) 200 according to the first embodiment.

The liquid discharge head 200 is provided with two print element substrates 400 that discharge a liquid. The print element substrate 400 includes a heater (not shown) configured to heat ink. The heater is heated, thereby generating bubbles in ink and discharging the liquid (ink) from orifices (not shown).

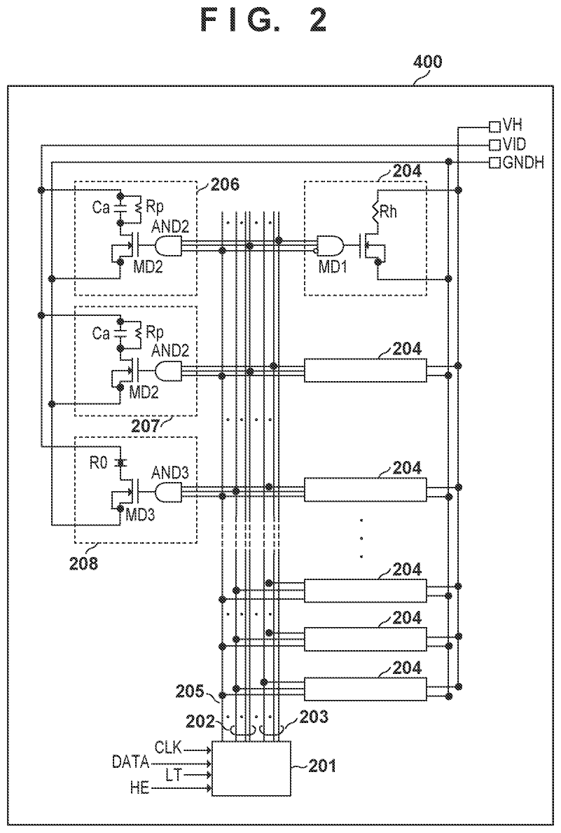

Next, circuits formed on the print element substrate 400 will be described with reference to FIGS. 1 and 2.

FIGS. 1 and 2 are circuit diagrams showing the circuit configuration of the print element substrate 400 according to the first embodiment. Here, FIG. 1 shows a circuit diagram in which one memory module 206 that is one of the features of the first embodiment is formed on the print element substrate. FIG. 2 shows a circuit diagram in which a plurality of (two) memory modules 206 are formed. The print element substrate 400 includes a plurality of discharge modules 204, the memory module (storage unit) 206, a short function module 208, and a control data supply circuit 201.

The discharge module 204 includes a pressure generation element (electrothermal transducer) Rh that generates energy to discharge the liquid from orifices (not shown) formed in the print element substrate 400, and a driving element MD1 and a logic circuit AND1 configured to drive the pressure generation element Rh. In the first embodiment, the driving element MD1 is a MOS transistor. Here, the MOS transistor has the role of a switch that decides whether to apply a voltage to the pressure generation element Rh. The logic circuit AND1 is an AND circuit configured to drive the driving element MD1 based on a signal from the control data supply circuit 201, and performs a logical operation of a plurality of signals. If the output of the AND circuit changes to high level, the pressure generation element Rh is driven. That is, if the output of the AND circuit changes to high level, the driving element MD1 is turned on to energize the pressure generation element Rh and generate heat. Bubbles are thus generated in ink, and the liquid (ink) is discharged from the orifices, thereby performing printing. A power supply voltage VH (for example, 24 V) is supplied as a power supply voltage to the opposite side of the pressure generation element Rh connected to the driving element MD1. On the other hand, the source side of the MOS transistor MD1 that is the driving element MD1 is connected to a ground potential GNDH.

The memory module 206 includes an anti-fuse element Ca, a parallel resistor Rp (resistor) connected in parallel with the anti-fuse element Ca, and a driving element MD2 and a logic circuit AND2 configured to write information to the anti-fuse element Ca. The anti-fuse element Ca stationarily holds information when an overvoltage is supplied to it. That is, the anti-fuse element Ca functions as a One Time Programmable (OTP) ROM as a memory that can be programmed only once. Before the overvoltage is supplied, the anti-fuse element Ca is in an insulated state. When the overvoltage is supplied, the anti-fuse element Ca changes to a resistance element (resistor) and is set to an energized state. Hence, the memory function is exhibited by, for example, determining the insulated state of the anti-fuse element Ca as “0” and the energized state as “1”. The parallel resistor Rp prevents information from being erroneously written to the anti-fuse element Ca as the overvoltage from a power supply voltage VID is applied across the anti-fuse element Ca although the driving element MD2 is in a nonconductive state. The driving element MD2 is, for example, a transistor. When recording information “1” in the anti-fuse element Ca, the driving element MD2 is driven to apply a voltage to the anti-fuse element Ca, and the anti-fuse element Ca is set to the energized state by the applied voltage, thereby storing the information “1”. The power supply voltage VID (for example, 24V) is supplied to the anti-fuse element Ca, and the ground potential GNDH is supplied to the source side of the MOS transistor MD2.

Note that although the power supply voltage VID of the anti-fuse element Ca and the power supply voltage VH of the pressure generation element Rh use independent power supply lines, if the minimum value of the voltage needed for write to the anti-fuse element is equal to or less than the power supply voltage VH, the power supply voltage VH may be used together with, for example, a step-down circuit.

The short function module 208 has the same element configuration as the memory module 206. After the anti-fuse element Ca is mounted, short-circuit processing (short-circuit) using an aluminum material is performed for the anti-fuse element. Note that the portion that undergoes the short-circuit processing by the aluminum material may be a simple resistance element or wiring element if it satisfies a short-circuit function. Here, a driving element of the short function module 208 is indicated by MD3, and a logic circuit is indicated by AND3.

The control data supply circuit 201 is a circuit configured to drive the driving elements MD1, MD2, and MD3, and includes, for example, a shift register (not shown) or a latch circuit (not shown). A clock signal (CLK), a data signal (DATA), a latch signal (LT), and a heat enable signal (HE) are inputted from the outside of the print element substrate 400 to the control data supply circuit 201 via terminals of the print element substrate 400. The data signal (DATA) includes information for selecting the discharge module 204, the memory module 206, and the short function module 208. The data signal (DATA) is inputted in a serial format in synchronism with the clock signal (CLK).

The control data supply circuit 201 receives the data signal (DATA) and generates a block selection signal, a group selection signal, and a switching signal based on the information included in the data signal (DATA). Based on these signals, the discharge module 204, the memory module 206, and the short function module 208 are selected and driven. The control data supply circuit 201 supplies, to the logic circuits (AND1 to AND3) the block selection signal via a signal line 202, the group selection signal via a signal line 203, and the switching signal via a signal line 205.

To time-divisionally drive the discharge module 204, the memory module 206, and the short function module 208, as shown in FIG. 1, the plurality of discharge modules 204 are divided into eight groups (G1, . . . , G8) each including three discharge modules 204. In addition, three blocks (1, 2, 3) are assigned to the discharge modules 204 of each group. This makes it possible to time-divisionally select and drive the discharge module 204, the memory module 206, and the short function module 208. Also, at the time of readout of the anti-fuse element (to be described later), it is possible to time-divisionally access the memory module 206 and the short function module 208. Here, the group selection signal is a signal used to select which group is to be driven when the plurality of discharge modules 204 are divided into a plurality of groups. The block selection signal is a signal used to select which pressure generation element Rh of a plurality of pressure generation elements Rh in the same group is to be driven. As the driving element MD1, a DMOS transistor (Double-diffused MOSFET) that is a MOS transistor and can resist a high voltage is used.

Here, as an example, the plurality of discharge modules 204 are divided into eight groups (G1, . . . , G8) each including three discharge modules 204. However, this embodiment is not limited to this, and the plurality of discharge modules 204 may be divided into eight groups each including 16 discharge modules 204.

In addition, the anti-fuse element Ca can be driven using the signal lines 202 and 203. At this time, the switching signal line 205 is used. By the switching signal line 205, a case where the anti-fuse element Ca is driven and a case where the discharge module 204 is driven are switched. Hence, the block selection signal, the group selection signal, and the switching signal are inputted to the logic circuit AND2 of the memory module 206. A signal according to the inputted signals is outputted from the logic circuit AND2 to the driving element MD2 of the memory module 206 to drive the anti-fuse element Ca, and the anti-fuse element Ca can be changed from the insulated state to the energized state. As the driving element MD2 of the memory module 206, a DMOS transistor is used, like the driving element MD1 of the discharge module 204. Also, the logic circuit AND2 of the memory module 206 is formed by a MOS transistor.

The block selection signal, the group selection signal, and the switching signal are inputted to the logic circuit AND3 of the short function module 208 as well. A signal according to the inputted signals is outputted from the logic circuit AND3 to the driving element MD3 of the short function module 208. As the driving element MD3, a DMOS transistor is used. The logic circuit AND3 is formed by a MOS transistor.

Which memory module 206 is to write information to the anti-fuse element Ca is decided by the block selection signal, the group selection signal, and the switching signal according to the signals CLK, DATA, LT, and HE.

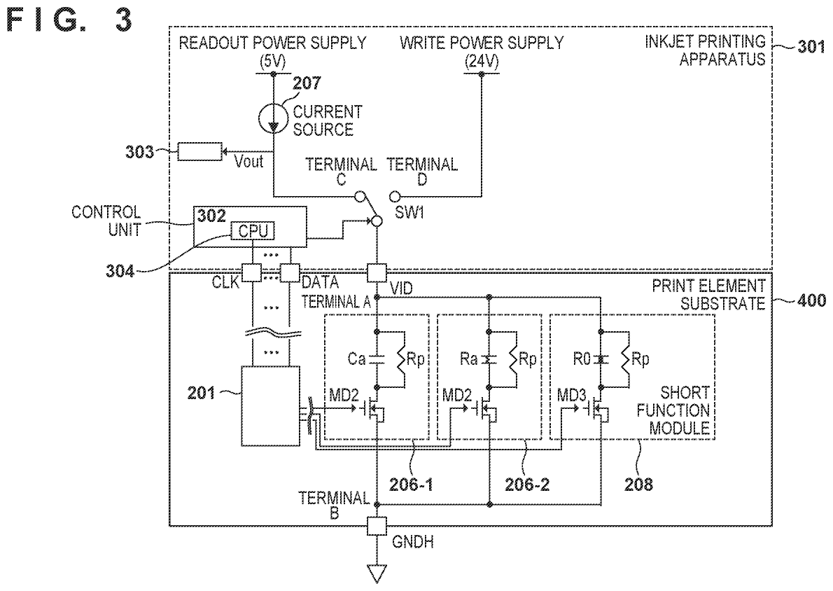

An operation in the write to the anti-fuse element Ca will be described next with reference to FIG. 3.

FIG. 3 is a view for explaining information write to the anti-fuse element Ca of the memory module 206 of the print element substrate according to the first embodiment.

In FIG. 3, a description will be made using an example in which two memory modules 206 are included, as shown in FIG. 2. FIG. 3 shows the relationship between the circuit configuration of the print element substrate 400 and an inkjet printing apparatus 301 according to the first embodiment.

The inkjet printing apparatus 301 includes a control unit 302 and a determination unit 303. The control unit 302 includes a CPU 304 and controls the operation of the print element substrate 400. The determination unit 303 discriminates whether the anti-fuse element Ca is in an insulated state or not. Also, the control unit 302 controls the inkjet printing apparatus 301 based on the result of discrimination by the determination unit 303.

Also, the control unit 302 performs switching control of a switch (SW1). If the switch SW1 is connected to a terminal C, the path between a readout power supply (for example, 5 V) and a terminal A of the anti-fuse element Ca is established. On the other hand, if the switch SW1 is connected to a terminal D, the path between a write power supply (for example, 24 V) and the terminal A of the anti-fuse element Ca is established.

Furthermore, the control unit 302 generates control data to be transmitted, via the CLK terminal and the DATA terminal of the print element substrate 400, to the internal control data supply circuit 201. The control data includes the clock signal (CLK), the data signal (DATA), the latch signal (LT), and the heat enable signal (HE). By the control data, drive control of the driving element MD2 of the memory module 206 and the driving element MD3 of the short function module 208 is performed.

If the switch SW1 is connected to the terminal D, the write power supply mounted in the inkjet printing apparatus is connected to the terminal A, and the ground mounted in the inkjet printing apparatus is connected to the terminal B on the ground side. Here, to write information to the anti-fuse element Ca, the driving element MD2 of the memory module 206 is set to an ON state. Thus, the high voltage VID is applied to a gate oxide film that forms the anti-fuse element Ca. The gate oxide film is thus broken, the anti-fuse element Ca is electrically set to a conductive state, and information is written. The anti-fuse element Ca that is a capacitive element before the write changes to a resistance element Ra after the write. Of the two memory modules 206, a memory module 206-1 shows a state in which information is not written to the anti-fuse element Ca (a state in which dielectric breakdown has not occurred). On the other hand, a memory module 206-2 shows a state in which information is written to the anti-fuse element, and the anti-fuse element changes to the resistance element Ra (a state in which dielectric breakdown has occurred).

An operation when reading out information recorded in the anti-fuse element Ca will be described next with reference to FIG. 3. Note that the discharge modules 204 and the like shown in FIGS. 1 and 2 are not illustrated in FIG. 3 for the descriptive convenience. When reading out information, the terminal A shown in FIG. 3 is connected to a current source 207 mounted in the printing apparatus, and the terminal B is connected to ground mounted in the printing apparatus. The short function module 208 is connected in parallel with each memory module 206.

In the first embodiment, when reading out information, a constant current is supplied from the current source 207 to the terminal A, and a voltage Vout generated in the terminal A is read by the printing apparatus, thereby discriminating the write state of the anti-fuse element Ca. In the first embodiment, the limit voltage of the current source 207 is set to 5 V.

First, in a state in which information is not written to the anti-fuse element Ca, like the memory module 206-1, the anti-fuse element Ca is insulated. For this reason, letting Rd2 be the ON resistance value of the driving element MD2, and is be the current value of the current source 207, an output voltage Vouta is given by

Vouta=is×(Rp+Rd2) (1)

On the other hand, in a state in which information is written to the anti-fuse element Ca, like the memory module 206-2, the anti-fuse element Ca functions as the resistance element Ra. For this reason, letting Rd2 be the ON resistance value of the driving element MD2, an output voltage Voutb is given by

Voutb=is×((Ra×Rp)/(Ra+Rp)+Rd2) (2)

Here, for example, if is =20 μA, Rp=70 kΩ, Rd2=1 kΩ, and Ra=1 kΩ, the output voltage Voutb is 0.05 V or less.

In the short function module 208, the anti-fuse element Ca has undergone short-circuit processing using an aluminum material. Hence, the anti-fuse element functions as a resistance element R0. For this reason, letting Rd3 be the ON resistance value of the driving element MD3, an output voltage Vouts is given by

Vouts=is×((R0×Rp)/(R0+Rp)+Rd3) (3)

Here, for example, if is =20 μA, Rp=70 kΩ, Rd3=1 kΩ, and R0=0.01 kΩ, the output voltage Vouts is 0.03 V or less.

Note that the resistance element R0 that has undergone short-circuit processing using an aluminum material need only satisfy a short-circuit function, like a simple resistance element or wiring element.

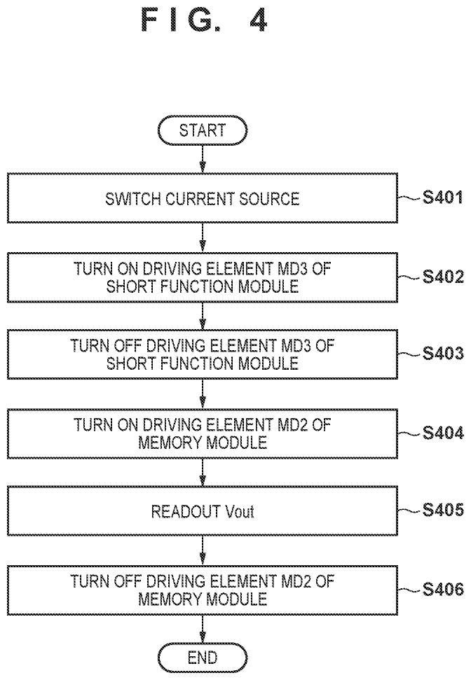

The procedure of the readout operation of the anti-fuse element Ca of the memory module 206-1 will be described next with reference to FIG. 4.

FIG. 4 is a flowchart for explaining readout processing of the anti-fuse element Ca by the control unit 302 of the inkjet printing apparatus 301 according to the first embodiment. Note that the processing shown in the flowchart is implemented by the CPU 304 executing a program stored in the memory (not shown) of the control unit 302.

In step S401, the CPU 304 switches the switch SW1 to the readout power supply (terminal C) to supply a constant current from the current source 207 to the terminal A. The process advances to step S402, and the CPU 304 temporarily sets the driving element MD3 of the short function module 208 in the ON state. As a result, the potential of the terminal A is set to 0.03 V or less, like the voltage Vouts. Then, the process advances to step S403, and the CPU 304 sets the driving element MD3 in an OFF state (open state). In step S404, the CPU 304 sets the driving element MD2 of the memory module 206-1 to which the anti-fuse element Ca is connected in the ON state. In step S405, the voltage Vout (information recorded in the anti-fuse element) is read out. The process advances to step S406, and after the voltage Vout is read out, the CPU 304 turns off the driving element MD2 of the memory module 206-1 to return it to the initial state, and ends the processing.

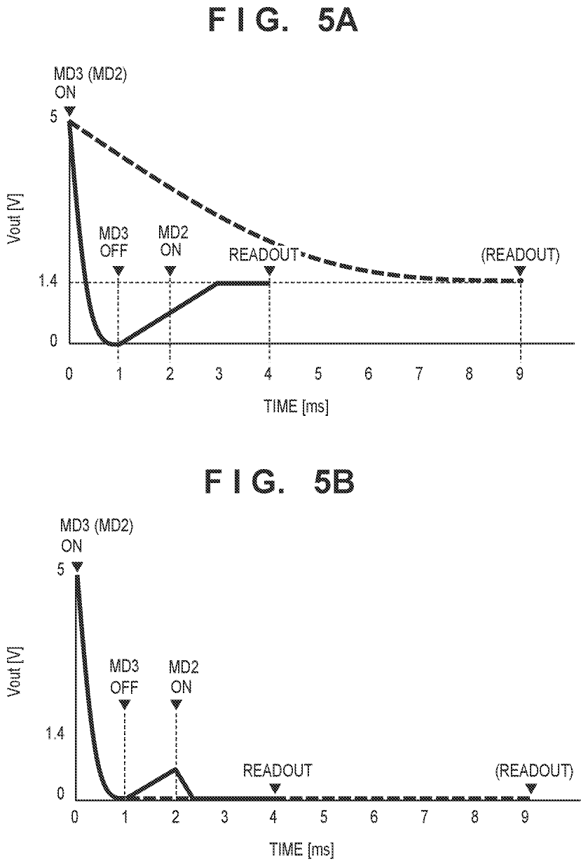

FIGS. 5A and 5B are views for explaining voltage waveforms in the readout operation of the anti-fuse element.

In FIG. 5A, the time-base waveform of the potential of the terminal Ain the readout operation of the anti-fuse element Ca of the memory module 206-1 is indicated by a solid line. In the first embodiment, the initial value of the voltage of the terminal A is 5V that is the limit voltage of the current source 207. When the driving element MD3 of the short function module 208 is set to the ON state (step S402), a current immediately flows to the resistance element R0 that has undergone the short-circuit processing. Hence, the voltage Vout lowers to 0.03 V or less, like the voltage Vouts. Next, when the driving element MD3 is set to the OFF state (step S403), the potential of the terminal A starts rising to return to the limit voltage of 5 V of the initial state. Next, when the driving element MD2 of the memory module 206-1 is set to the ON state (step S404), a current flows to the memory module 206-1, and the voltage reaches the same voltage value (1.4 V) as the voltage Vouta. After the voltage change is thus stabilized, the control unit 302 of the inkjet printing apparatus 301 reads the voltage value of the terminal A.

A waveform indicated by a broken line in FIG. 5A is the voltage waveform of the terminal A when the driving element MD3 of the short function module 208 is not operated, and only the driving element MD2 of the memory module 206-1 is operated. (MD2) with parentheses indicates the ON state start timing of the driving element MD2 of the memory module 206-1, and (readout) indicates the readout timing of the voltage of the terminal A.

The waveform indicated by the broken line is the voltage waveform of the terminal A in a case where the short function module 208 is not mounted or is unused, and shows an example of a comparison target concerning the presence/absence of the short function module 208. At this time, when the driving element MD2 of the memory module 206-1 is set to the ON state, the voltage of the terminal A moderately reaches from the initial value of 5 V to the voltage Vouta (1.4 V). The phenomenon that a moderate waveform is obtained occurs at this time because of the transient phenomenon at the time of voltage drop caused by the influence of the capacitance component of the anti-fuse element Ca of the memory module 206-1 and the capacitance component of the circuit of the inkjet printing apparatus connected to the terminal A. Here, to correctly measure the voltage value of the terminal A at the time of readout, it is necessary to wait until the voltage sufficiently lowers to a steady state. In this case, however, the time until the voltage sufficiently lowers to the steady state becomes long, and the time needed for readout cannot be shortened.

Hence, in the first embodiment, when reading out the voltage of the terminal A of the anti-fuse element Ca of the memory module 206-1, the short function module 208 indicated by the solid line is operated to shorten the time until the voltage of the terminal A sufficiently lowers to the steady state. Hence, the standby time until the voltage of the terminal A lowers to the steady state is shortened, and accordingly, the readout timing of the anti-fuse element can be made early.

In FIG. 5B, the time-base waveform of the potential of the terminal A in the readout operation in the memory module 206-2 is indicated by a solid line. In the memory module 206-2 as well, after the driving element MD3 of the short function module 208 is temporarily set in the ON state and returned to the OFF state, the shape of the waveform until the driving element MD2 of the memory module 206-2 is turned on is the same as in FIG. 5A. When the driving element MD2 of the memory module 206-2 is turned on, the anti-fuse element Ca functions as the resistance element Ra. Hence, the voltage Voutb of the terminal A becomes 0.05 V or less. After the terminal change of the terminal A is thus stabilized, the control unit 302 of the inkjet printing apparatus 301 reads the voltage value of the terminal A.

A waveform indicated by a broken line in FIG. 5B is the voltage waveform of the terminal A when the driving element MD3 of the short function module 208 is not operated, and only the driving element MD2 of the memory module 206-2 is operated. (MD2) with parentheses indicates the ON state start timing of the driving element MD2, and (readout) indicates the readout timing of the voltage of the terminal A. When the driving element MD2 of the memory module 206-2 is set to the ON state, the anti-fuse element Ca functions as the resistance element Ra, and therefore, the voltage Voutb of the terminal A becomes 0.05 V or less.

In the example shown in FIGS. 5A and 5B, in a case where the short function module 208 is not mounted or is unused, the driving element MD2 of the memory module 206 is turned on, and after standing by for 9 ms, the voltage of the terminal A is read. On the other hand, when the driving element MD3 of the short function module 208 is operated, the standby time of readout can be shortened to 4 ms.

As described above, according to the first embodiment, it is possible to speed up the readout operation of the terminal voltage of the anti-fuse element without using an external power supply configured to temporarily over-precharge the terminal voltage of the anti-fuse element.

### Second Embodiment

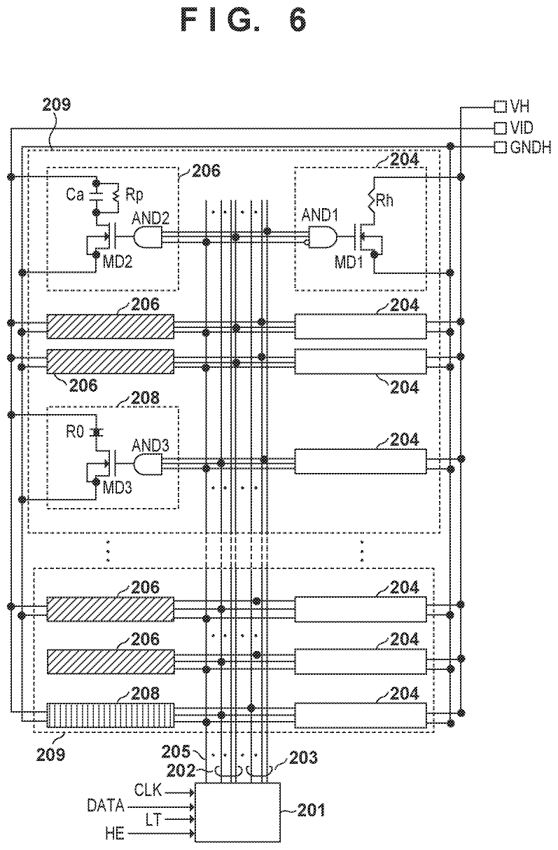

The second embodiment of the present invention will be described next with reference to FIGS. 6, 7, and 10. In the above-described first embodiment, the configuration including one or two memory modules 206 and one short function module 208, as shown in FIGS. 1 and 2, has been described.

On the other hand, in the second embodiment, as shown in FIG. 6, defining an aggregate of modules 204, 206, and 208 as a module group 209, a configuration in which a plurality of module groups 209 are formed will be described. That is, a print element substrate 400 according to the second embodiment includes a plurality of short function modules 208.

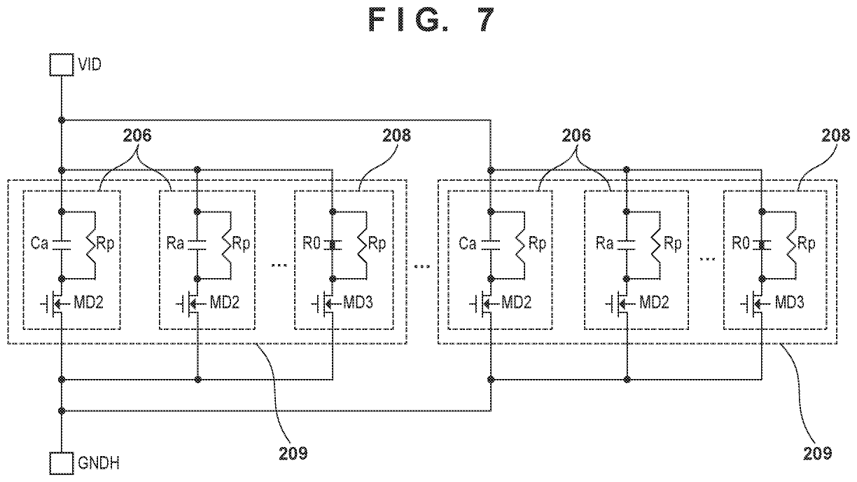

FIG. 7 is a view for explaining connection between a plurality of memory modules 206 and the short function modules 208 in each module group.

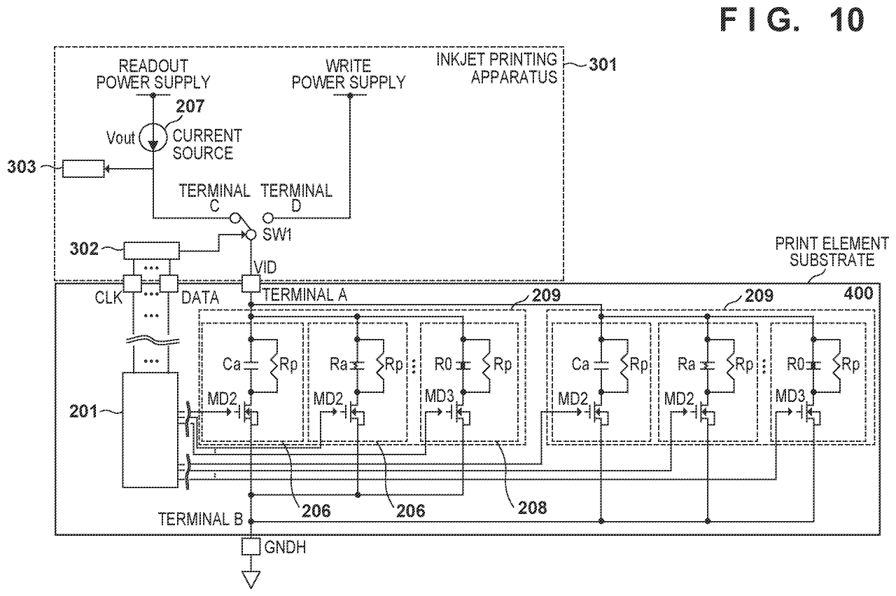

FIG. 10 is a connection diagram of an inkjet printing apparatus 301 and the print element substrate 400 according to the second embodiment.

The circuit configuration in each module of the print element substrate 400 is the same as in the above-described first embodiment, and a description thereof will be omitted. The write operation of an anti-fuse element Ca is also the same as in the first embodiment, and a description thereof will be omitted.

Concerning y groups each including x memory modules 206 and at least one short function module, the memory modules 206 and the short function module 208 are controlled on a group basis by an output signal of a control data supply circuit 201. More specifically, the memory module 206 receives at least one bit each of a block selection signal via a signal line 202, a group selection signal via a signal line 203, and a switching signal via a signal line 205, thereby time-divisionally driving the anti-fuse element Ca.

As for the short function module 208 as well, each short function module 208 receives at least one bit each of the block selection signal, the group selection signal, and the switching signal, thereby time-divisionally driving a resistance element R0.

At this time, which one of the discharge module 204 and the memory module 206 is to be driven is selected using the switching signal via the signal line 205. More specifically, if the switching signal is at low level, the discharge module 204 is selected, and if the switching signal is at high level, the memory module 206 is selected. The logic is configured by the switching signal such that all pressure generation elements Rh and all anti-fuse elements Ca are not simultaneously driven. As for the short function module 208 as well, which one of the discharge module 204 and the short function module 208 is to be driven is selected by the switching signal, and the logic is configured such that all pressure generation elements Rh and all resistance elements R0 are not simultaneously driven.

Here, if the switching signal is a 1-bit signal, the relationship between the total number x′ of anti-fuse elements Ca and resistance elements R0 in one memory group and the number n of time division selection signals is represented by x′≤n. The relationship between the number y of memory groups and the number m of block selection signals is represented by y≤m. A configuration for controlling anti-fuse elements Ca and resistance elements R0 in number exceeding (n×m) may be formed by providing a plurality of bits of print element/memory switching signals.

An operation at the time of readout will be described next. The basic readout operation is the same as in the first embodiment. In the configuration including a plurality of short function modules 208, even if the resistance element R0 of a memory module different from the anti-fuse element Ca of the readout target is driven and controlled, the same effect as in the first embodiment can be obtained. However, if the number of connected memory module groups increases, the parasitic capacitance becomes large and affects the delay of the readout speed. Hence, it is preferable to drive the resistance element R0 of the same module group as the anti-fuse element Ca of the target of the readout operation.

Note that the resistance element R0 is not limited to short-circuit processing of the anti-fuse element Ca using an aluminum material and need only satisfy a short-circuit function, like a simple resistance element or wiring element.

As described above, according to the second embodiment, the aggregate of modules is divisionally driven as a module group. Hence, even if the number of memory modules is increased, the same effect as in the first embodiment can be obtained.

### Third Embodiment

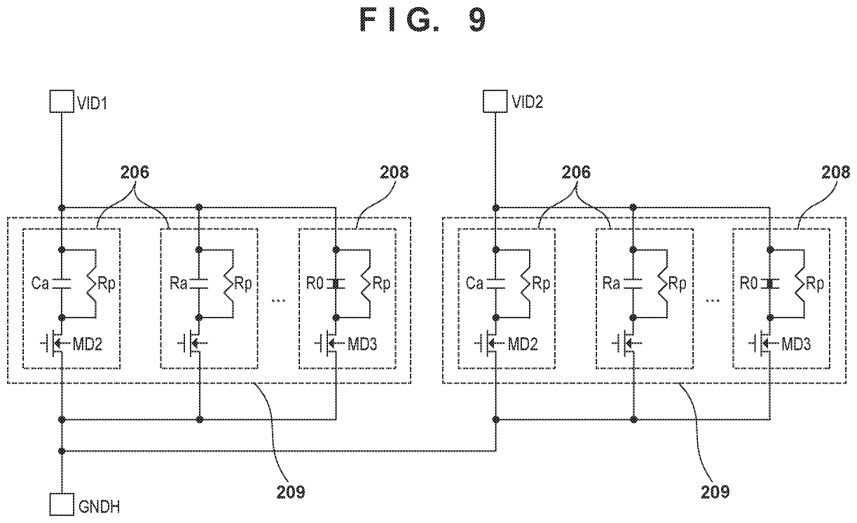

The third embodiment will be described with reference to FIG. 9. In the second embodiment, as shown in FIG. 7, defining an aggregate of the modules 204, 206, and 208 as a module group 209, a plurality of module groups 209 are formed, and the module groups are connected to a common power supply.

FIG. 9 is a view for explaining the module groups of a print element substrate according to the third embodiment.

FIG. 9 according to the third embodiment shows module groups of a print element substrate in which module groups 209 are connected to different power supply terminals VID1 and VID2. In this configuration, the readout operation procedure shown in FIG. 4 is simultaneously concurrently executed for the modules, thereby simultaneously reading out the terminal voltages of anti-fuse elements Ca of a plurality of modules.

Hence, when reading out information of all anti-fuse elements mounted on the print element substrate, the operation can be speeded up.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2022-039554 filed on Mar. 14, 2022, which is hereby incorporated by reference herein in its entirety.

What is claimed is:

1. A readout method of a memory module of a substrate including the memory module including an anti-fuse element, and a function module connected in parallel with the memory module and including a resistance element, comprising:
setting the function module to a conducted state when reading out the memory module;
setting the function module from the conducted state to an open state following the setting the function module to the conducted state; and
reading out a terminal voltage of the anti-fuse element by setting the memory module to the conducted state following the setting the function module from the conducted state to the open state.

2. The method according to claim 1, wherein
the memory module further includes a first resistor connected in parallel with the anti-fuse element, and a first driving element configured to control conduction of the anti-fuse element,
the function module further includes a second driving element configured to control conduction of the resistance element, and
conduction of the memory module in the setting the function module from the conducted state to the open state is done by controlling the first driving element, and conduction of the function module in the setting the function module to the conducted state is done by controlling the second driving element.

3. The method according to claim 2, wherein in the setting the function module to the conducted state, a voltage applied to the anti-fuse element is lowered to a voltage based on a resistance value of the resistance element, an ON resistance value of the second driving element, and a current value.

4. The method according to claim 1, wherein
a current is supplied from a common current source to the memory module and the function module, and
the method further comprises switching the current source that supplies the current to the memory module between write to the memory module and readout from the memory module.

5. The method according to claim 1, wherein the terminal voltage of the anti-fuse element is a voltage generated in the anti-fuse element in accordance with a current supplied from a current source to the memory module in readout from the memory module.

6. The method according to claim 1, wherein a plurality of memory modules and a plurality of function modules provided on the substrate are divided into a plurality of groups each including at least a plurality of memory modules and one function module, and the setting the function module to the conducted state, the setting the function module from the conducted state to the open state, and the reading out are executed for each of the plurality of groups.

7. The method according to claim 6, wherein the plurality of groups are connected to different current sources, thereby executing the setting the function module to the conducted state, the setting the function module from the conducted state to the open state, and the reading out concurrently for each of the plurality of groups.

8. A printing apparatus for performing printing using a printhead including a print element substrate including a memory module including an anti-fuse element, and a function module connected in parallel with the memory module and including a resistance element connected in place of the anti-fuse element of the memory module, comprising
a control unit,
wherein when reading out the memory module, the control unit sets the function module in a conducted state, sets the function module from the conducted state to an open state, and then sets the memory module to the conducted state, thereby reading out a terminal voltage of the anti-fuse element.

9. The apparatus according to claim 8, wherein
the memory module further includes a first resistor connected in parallel with the anti-fuse element, and a first driving element configured to control conduction of the anti-fuse element,
the function module further includes a second driving element configured to control conduction of the resistance element, and
the control unit drives and conducts the first driving element of the memory module, and drives and conducts the second driving element of the function module.

10. The apparatus according to claim 9, wherein the function module is set to the conducted state, thereby lowering a voltage applied to the anti-fuse element to a voltage based on a resistance value of the resistance element, an ON resistance value of the second driving element, and a current value.

11. The apparatus according to claim 8, wherein a current is supplied from a common current source to the memory module and the function module, and the control unit switches the current source that supplies the current to the memory module between write to the memory module and readout from the memory module.

12. The apparatus according to claim 8, wherein the terminal voltage of the anti-fuse element is a voltage generated in the anti-fuse element in accordance with a current supplied from a current source to the memory module in readout from the memory module.

13. The apparatus according to claim 8, wherein the control unit further divides a plurality of memory modules and a plurality of function modules provided on the print element substrate into a plurality of groups each including at least a plurality of memory modules and one function module, and in each of the plurality of groups, when reading out the memory module, sets the function module to the conducted state, sets the function module from the conducted state to the open state, and then sets the memory module to the conducted state, thereby reading out the terminal voltage of the anti-fuse element.

14. The apparatus according to claim 13, wherein the plurality of groups are connected to different current sources, thereby causing the control unit to execute control operations concurrently for each of the plurality of groups.
